(19) United States
(12) Patent Application Publication
(10) Pub. No.: US 2017/0227847 A1
(43) Pub. Date: Aug. 10, 2017

(54) SURFACE-MODIFIED STRUCTURE AND MODIFYING METHOD THEREOF

(71) Applicant: I-SHAN KE, New Taipei City (TW)

(72) Inventor: Yu-Hsun LIN, Taichung City (TW)

(21) Appl. No.: 15/260,309

(22) Filed: Sep. 8, 2016

Related U.S. Application Data
(60) Provisional application No. 62/291,519, filed on Feb. 5, 2016.

(51) Int. Cl. G03F 7/11; G03F 7/16

(52) U.S. Cl. CPC G03F 7/11; G03F 7/16

(57) ABSTRACT

A surface-modified structure and a method of modifying a surface are provided. The surface-modified structure includes a surface having a carboxylate group, a modifier represented by NH2-SO2- and an R group. A hydrogen bond is formed between the carboxylate group of the surface and the modifier. The R group is covalently bonded to the modifier.

### RELATED APPLICATIONS

This application claims priority to U.S. Provisional Application Ser. No. 62/291,519, filed Feb. 5, 2016, which is herein incorporated by reference.

### BACKGROUND

Field of Disclosure

The present disclosure relates to modify a surface. More particularly, the present disclosure relates to modify a surface with carboxylate groups.

Description of Related Art

The conventional method used to change the surface properties is to modify the contact angle of the surface. However, the contact angle is hard to be modified unless an additional treatment process is applied. An UV cure process can be applied to modify the contact angle of the surface by breaking the chemical bond on the surface and making the chemical bond rearrangement. Another different kind of treatments can also be used for this purpose. The key factor of the treatments is applied a sufficient energy to the organic group of the surface for chemical bond cleavage, and the chemical bond would start cleavage and re-bonding process that induce the chemical bond rearrangement reaction. The energy of the treatments can be supplied from electron beam (e-beam), plasma treatment or ion implantation.

For instance, the plasma treatment species can be Ar, N₂, H₂, O₂, CxFy gas or the other conventional plasma gas. The ion implant species can be Ar, N₂, He, Boron or Phosphine contain molecular or other conventional implant gas.

However, such kinds of treatment need an additional cost and apparatus for it. Moreover, the bombard treatment process will damage the substrate. Since the bombard spices not only break the organic bond but also through the organic film or substrate that cause other side effects. Therefore, it is essential for a method of modifying a surface, which can easily change the surface properties.

### SUMMARY

In view of the issue un-met in the art, the present disclosure provides a surface-modified structure and a method of modifying a surface, which can easily change the surface properties without other side effects such as the damage of the organic film or substrate.

The present disclosure provides a surface-modified structure. The surface-modified structure includes a surface having a carboxylate group, a modifier represented by NH₂—SO₂— and an R group. A hydrogen bond is formed between the carboxylate group of the surface and the modifier. The R group is covalently bonded to the modifier.

In various embodiments of the present disclosure, the R group is selected from a group consisting of fluoroalkyl group, alkyl group, polymer group, silanol group, metal group and metal oxide group.

In various embodiments of the present disclosure, the hydrogen bond is formed between NH₂ of the modifier and the carboxylate group.

In various embodiments of the present disclosure, the hydrogen bond is formed between the modifier and O⁻ of the carboxylate group.

In various embodiments of the present disclosure, the R group is covalently bonded to S of the modifier.

In various embodiments of the present disclosure, the R group is fluoroalkyl group represented by CₓF₂ₓ₊₁, and x is an integer from 1 to 6.

In various embodiments of the present disclosure, the R group is C₄F₉.

In various embodiments of the present disclosure, the R group is alkyl group comprising C1-C12 alkyl group.

In various embodiments of the present disclosure, the R group is polymer group including —(CH₂CCH₃COOCH₃)ₙ—, —(CH₂CCH₃COOH)ₙ—, —(CH₂CCH₃COOR1)ₙ-, —(CH₂CHCOOR1)ₙ-, —(CH₂CHC₆H₅)ₙ— and —(CH₂CHOH)ₙ—, wherein R1 comprises methyl group, ethyl group, propyl group, benzyl group, phenol group, admantyl group, —C₆H₄COOH, lactone group, acid labile group (ALG), or the combination thereof. The acid labile group will be leaving after reaction with acid in baking step, the acid may come from thermal acid generator (TAG) or photo acid generator (PAG), the PAG is 193 nm or EUV sensitive PAG. And n is an integer from 1 to 20.

In various embodiments of the present disclosure, the R group is metal group comprising titanium (Ti) or tungsten (W).

In various embodiments of the present disclosure, the R group is metal oxide group comprising TiO_{y}, LaO_{y}, HfO_{y} or SnO_{y}, and y is in a range of 1.5 to 3.

The present disclosure provides a method of modifying a surface, and the method includes following steps. A substrate having the surface with a carboxylate group is provided. A compound represented by NH₂—SO₂—R is formed, which R is selected from a group consisting of fluoroalkyl group, alkyl group, polymer group, silanol group, metal group and metal oxide group. A hydrogen bond is formed between the compound and the carboxylate group of the surface.

In various embodiments of the present disclosure, the process of forming the compound represented by NH₂—SO₂—R includes following steps. A modifier represented by NH₂—SO₂— is provided. The modifier is covalently bonded to R.

In various embodiments of the present disclosure, the process of forming the hydrogen bond between the compound and the carboxylate group of the surface includes following steps. A first solution including the compound is prepared. The first solution is applied to the surface of the substrate.

In various embodiments of the present disclosure, the process of applying the first solution to the surface of the substrate includes following step. The surface of the substrate is rinsed with the first solution, or the first solution is coated to the surface of the substrate.

In various embodiments of the present disclosure, the first solution includes the compound and deionized water. The compound is in a range of 0.005 to 5 part by weight, and the deionized water is in a range of 95 to 99 parts by weight.

In various embodiments of the present disclosure, the first solution further includes a surfactant. The surfactant is in a range of 0.05 to 0.8 part by weight.

In various embodiments of the present disclosure, the process of forming the hydrogen bond between the compound and the carboxylate group of the surface is under an alkaline condition. The pH value is more than 7 according to some embodiments.

In various embodiments of the present disclosure, R is the fluoroalkyl group represented by CₓF₂ₓ₊₁, and x is an integer from 1 to 6.

In various embodiments of the present disclosure, R is C₄F₉.

In various embodiments of the present disclosure, R group is polymer group derived from a material including poly(methyl methacrylate) (PMMA), poly methacrylic acid, polymethacrylate polymer, polyacrylate polymer, polyhydrostyrene or poly vinyl alcohol.

In various embodiments of the present disclosure, R group is polymer group including —(CH₂CCH₃COOCH₃)ₙ— (derived from PMMA), —(CH₂CCH₃COOH)ₙ— (derived from poly methacrylic acid), —(CH₂CCH₃COOR1)ₙ- (derived from polymethacrylate polymer), —(CH₂CHCOOR1)ₙ- (derived from polyacrylate polymer), —(CH₂CHC₆H₅)ₙ— (derived from polyhydrostyrene) or —(CH₂CHOH)ₙ— (derived from poly vinyl alcohol). R1 group may be a liner, branch, or cyclic alkyl structure. For example, the R1 may be methyl group, ethyl group, propyl group, benzyl group, phenol group, admantyl group, —C₆H₄COOH, lactone group, acid labile group (ALG), or the combination thereof. The acid labile group will be leaving after reaction with acid in baking step, the acid may come from thermal acid generator (TAG) or photo acid generator (PAG), the PAG is 193 nm or EUV sensitive PAG, and n is an integer from 1 to 20. For example, the ALG may be ethyl admantyl, methyl admantyl.

These and other features, aspects, and advantages of the present disclosure will become better understood with reference to the following description and appended claims.

It is to be understood that both the foregoing general description and the following detailed description are by examples, and are intended to provide further explanation of the invention as claimed.

### BRIEF DESCRIPTION OF THE DRAWINGS

The disclosure could be more fully understood by reading the following detailed description of the embodiment, with reference made to the accompanying drawings as follows:

FIG. 1 is a schematic view of a surface-modified structure according to various embodiments of the present disclosure.

### DETAILED DESCRIPTION

The following embodiments are disclosed for detailed description. For illustration clarity, many details of practice are explained in the following descriptions. However, it should be understood that these details of practice do not intend to limit the present invention. That is, these details of practice are not necessary in parts of embodiments of the present invention. Furthermore, for simplifying the drawings, some of the conventional structures and elements are shown with schematic illustrations.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, or “includes” and/or “including” or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

As aforementioned problems, it is noted that the conventional methods used to change the surface properties often damage the substrate and have an additional cost and apparatus. Therefore, it is essential for a method which can easily modify a surface of an organic film or a substrate without other side effects.

Accordingly, the present disclosure provides a surface-modified structure and a method of modifying a surface, can easily change the surface properties without other side effects such as the damage of the organic film or substrate.

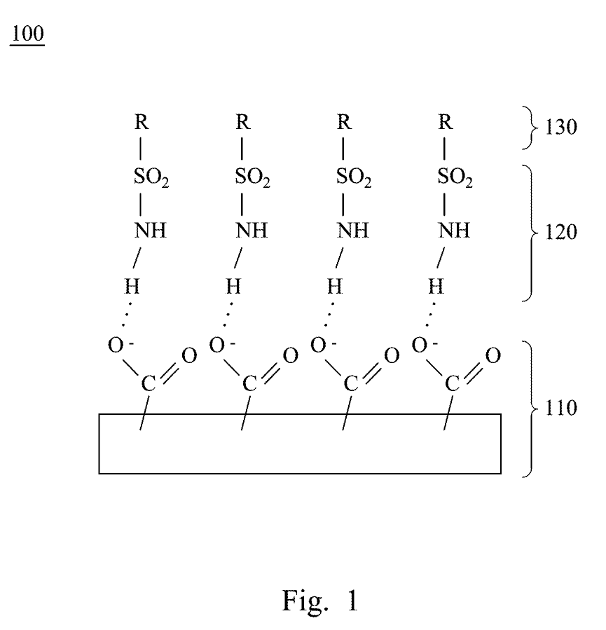

Please refer to FIG. 1. FIG. 1 is a schematic view of a surface-modified structure according to various embodiments of the present disclosure. FIG. 1 illustrates a surface-modified structure 100. The surface-modified structure 100 includes a substrate 110 having carboxylate groups on its surface, a modifier 120 represented by NH₂—SO₂— and an R group 130. A hydrogen bond is formed between the carboxylate group of the surface of the substrate 110 and the modifier 120. The R group 130 is covalently bonded to the modifier 120.

In details, the hydrogen bond is formed between NH₂ of the modifier 120 and the carboxylate group of the surface of the substrate 110. In some embodiments, the modifier 120 functions as a linker to connect the substrate 110 and the R group 130 in order to change the property of the surface of the substrate 110.

In some embodiments of the present disclosure, the R group 130 is covalently bonded to S of the modifier 120. The R group 130, which is a moiety with a desired property, is selected from a group consisting of fluoroalkyl group, alkyl group, polymer group, silanol group, metal group and metal oxide group.

In some embodiments of the present disclosure, the R group 130 is fluoroalkyl group represented by CₓF₂ₓ₊₁, and x is an integer from 1 to 6. More preferably, the R group 130 is C₄F₉.

In some embodiments of the present disclosure, the R group 130 is alkyl group including C1-C12 alkyl group. In another embodiments, the R group 130 is polymer group derived from a material including poly(methyl methacrylate) (PMMA), poly methacrylic acid, polymethacrylate polymer, polyacrylate polymer, polyhydrostyrene or poly vinyl alcohol.

In some embodiments of the present disclosure, the R group 130 is polymer group including —(CH₂CCH₃COOCH₃)ₙ— (derived from PMMA), —(CH₂CCH₃COOH)ₙ— (derived from poly methacrylic acid), —(CH₂CCH₃COOR1)ₙ- (derived from polymethacrylate polymer), —(CH₂CHCOOR1)n- (derived from polyacrylate polymer), —(CH₂CHC₆H₅)ₙ— (derived from polyhydrostyrene) or —(CH₂CHOH)ₙ— (derived from poly vinyl alcohol). R1 group may be a liner, branch, or cyclic alkyl structure. For example, the R1 may be methyl group, ethyl group, propyl group, benzyl group, phenol group, admantyl group, —C₆H₄COOH, lactone group, acid labile group (ALG), or the combination thereof. The acid labile group will be leaving after reaction with acid in baking step, the acid may come from thermal acid generator (TAG) or photo acid generator (PAG), the PAG is 193 nm or EUV sensitive PAG, and n is an integer from 1 to 20. For example, the ALG may be ethyl admantyl, methyl admantyl.

In other embodiments, the R group 130 is metal group including titanium (Ti) or tungsten (W). Besides, the R group 130 may be metal oxide group including TiO_{y}, LaO_{y}, HfO_{y} or SnO_{y}, and y is in a range of 1.5 to 3 according to some embodiments of the present disclosure.

In some embodiments, the surface having the carboxylate group of the present disclosure may be a surface of glass, a semiconductor wafer, a photoresist or furniture.

In an embodiment, the surface having the carboxylate group is a surface of the photoresist. In such embodiment, when the surface of the photoresist is hydrophobic, a water stain is formed after drying steps of wet etching, wet developing and wet cleaning process, and the water stain may become a defect during a semiconductor manufacturing process. The drying step may be spin-drying. Under such a scenario, the modifier 120 of the present disclosure may be used to modify the hydrophobic surface of the photoresist. The modifier 120 may be covalently bonded to the R group 130, which is a moiety with a desired property. In some embodiments, the R group is C₄F₉. In such embodiment, the modifier 120 is connected to the carboxylate group of the surface of the photoresist through a hydrogen bond so as to modify the property of the surface of the photoresist, and further prevent the formation of the water stain after the spin-drying step.

In view of the issue un-met in the art, the present disclosure also provides a method of modifying a surface, and the method includes following steps. A substrate having the surface with a carboxylate group is provided. A compound represented by NH₂—SO₂—R is formed, which R is selected from a group consisting of fluoroalkyl group, alkyl group, hydrophilic polymer group, hydrophobic polymer group, silanol group, metal group and metal oxide group. A hydrogen bond is formed between the compound and the carboxylate group of the surface.

In some embodiments, the R group is hydrophilic polymer group derived from a hydrophilic material including poly(methyl methacrylate) (PMMA), poly methacrylic acid, polymethacrylate polymer, polyacrylate polymer, polyhydrostyrene or poly vinyl alcohol.

In some embodiments, the R group is hydrophilic polymer group including —(CH₂CCH₃COOCH₃)ₙ— (derived from PMMA), —(CH₂CCH₃COOH)ₙ— (derived from poly methacrylic acid), —(CH₂CCH₃COOR1)ₙ- (derived from polymethacrylate polymer), —(CH₂CHCOOR1)ₙ- (derived from polyacrylate polymer), —(CH₂CHC₆H₅)ₙ— (derived from polyhydrostyrene) or —(CH₂CHOH)n- (derived from poly vinyl alcohol). R1 group may be a liner, branch, or cyclic alkyl structure. For example, the R1 may be methyl group, ethyl group, propyl group, benzyl group, phenol group, admantyl group, —C₆H₄COOH, lactone group, acid labile group (ALG), or the combination thereof. The acid labile group will be leaving after reaction with acid in baking step, the acid may come from thermal acid generator (TAG) or photo acid generator (PAG), the PAG is 193 nm or EUV sensitive PAG, and n is an integer from 1 to 20. For example, the ALG may be ethyl admantyl, methyl admantyl.

In some embodiments, the compound represented by NH₂—SO₂—R is formed first, and then the compound is connected to the carboxylate group of the surface through the hydrogen bond. In details, the process of forming the compound represented by NH₂—SO₂—R may include following steps. A modifier represented by NH₂—SO₂— is provided, and the modifier is covalently bonded to R, which is a moiety having the desired property. One should note that the examples of R may refer to the descriptions of the counterparts in FIG. 1, and hence are not repeat herein.

In some embodiments, the process of forming the hydrogen bond between the compound and the carboxylate group of the surface includes following steps. A first solution including the compound is prepared, and the first solution is applied to the surface of the substrate. In details, the first solution may include the compound and deionized water. Furthermore, the compound may be in a range of 0.005 to 5 part by weight, and the deionized water may be in a range of 95 to 99 parts by weight. In some embodiments, the first solution may further include a surfactant, and the surfactant may be in a range of 0.05 to 0.8 part by weight.

In some embodiments, the process of applying the first solution to the surface of the substrate includes following step. The surface of the substrate may be rinsed with the first solution, or the first solution may be coated to the surface of the substrate.

In some embodiments, the process of forming the hydrogen bond between the compound and the carboxylate group of the surface is under an alkaline condition because the hydrogen bond between the compound and the carboxylate group is more easily formed under the alkaline condition.

In an embodiment, a substrate having a surface with a carboxylate group is a photoresist. In such embodiment, a surface of the photoresist is hydrophobic, so that a watermark is easily formed on the surface of the photoresist during the process of wet etching, wet developing and wet cleaning process. Under such a scenario, the watermark is often broken into a smaller water drop after the spin-drying step of the semiconductor manufacturing process. Since the smaller water drop has strong van der waals force to adhere on the surface of the photoresist, the smaller water drop is dried to become a water stain, which turns into a defect during the semiconductor manufacturing process.

In order to avoid above-mentioned defect, the modifying method of the present disclosure is applied to the surface of the photoresist before the spin-drying step according to an embodiment. In such embodiment, a first solution is prepared first, and the first solution includes a compound in a range of 0.005 to 5 part by weight and deionized water in a range of 95 to 99 parts by weight. In addition, the first solution may further include the surfactant in a range of 0.005 to 0.8 part by weight, and the surfactant can reduce the capillary force between two adjacent photoresist lines while applying the first solution to the photoresist.

The surfactant additive can reduce surface tension, the surfactant additive may composed of non-ionic surfactant, or ionic surfactant. The surfactant loading may be 50 ppm to 8000 ppm. The surfactant loading may be about 80 ppm to 2000 ppm. In some embodiment, the surfactant is selected from Air Product company surfynol 104, surfynol 104a, surfynol 420, surfynol 440, surfynol 465, surfynol 485, Daikin industries LTD. UNIDYNE DSN-403N, UNIDYNE NS-9013, 3M Novec 4200, Novec 4300, Novec 1230, Novec1700, Novec7200, Novec2708, Novec7100, Novec1908, Novec7500, Novec2704, FC3283, FC40, FC4430, FC4432, FC4400, FC5000, FC770, FC226, FC600, FC430, FC72. FC43, FC40, FC4000, FC4434. MERCK Tivida FL2300, Tivida FL2200, Tivida FL2500. Dupont Capstone FS-22, Capstone FS-31, Capstone FS-30, Capstone FS-61, Capstone FS-63, Capstone FS-64, Capstone FS-81, Capstone FS-83. These surfactants disclosed above are only exemplary, the real workable surfactants for reducing the surface tension are not limited to these disclosed above.

In such embodiment, the compound is represented by NH₂—SO₂—R, and R is the fluoroalkyl group represented by CₓF₂ₓ₊₁, and x is an integer from 1 to 6. In details, R may be C₄F₉.

Next, the first solution may be applied to the surface of the photoresist by rinsing the surface with the first solution or coating the first solution to the surface. A hydrogen bond may be formed between the compound in the first solution and the carboxylate group of the surface of the photoresist. In other words, the compound in the first solution may be connected to the surface of the photoresist by a hydrogen bond formed between the —NH₂ of the compound and the carboxylate group of the surface of the photoresist. Preferably, the compound may be represented by NH₂—SO₂—C₄F₉.

After applying the first solution to the surface of the photoresist, the surface of the photoresist may be rinsed together with deionized water or CO2 water. In another embodiment, after applying the first solution to the surface of the photoresist, the surface of the photoresist may be rinsed by additional deionized water or CO2 water to remove the other components in the first solution, which are not connected to the surface of the photoresist. Then, the surface of the photoresist is spin-dried to remove the remaining liquid. In another embodiments, the surface of the photoresist is spin-dried directly after applying the first solution to the surface of the photoresist without the rinsing step.

In an embodiment, after the above modifying method of the present disclosure, the surface of the photoresist has a surface-modified structure including the compound represented by NH₂—SO₂—C₄F₉.

The following experiment is a comparison of the photoresist having the surface-modified structure of the present disclosure or not, and the surface-modified structure includes NH₂—SO₂—C₄F₉. In such experiment, the amount of water stains and particles was counted, and the particles formed on the surface may be the impurities during the semiconductor manufacturing process, organic photoresist polymer, inorganic contamination, impurity leaching from substrate, or the dust in the air. The result of the experiment is shown in Table 1.

TABLE 1

| | A modified surface (with | A surface without |
|---|---|---|
| | NH₂—SO₂—C₄F₉) | modifying |
| The amount of water | 0 | 500 |
| stains | | |
| The amount of particles | 5 | 50 |

Table 1 shows that the amount of water stains and particles on the modified surface are less than those on the surface without modifying. Therefore, it can be seen that the surface-modified structure of the present disclosure has an antifouling function to optimize the semiconductor manufacturing process. In other words, the surface-modified structure made by the modifying method of the present disclosure can improve and optimize the semiconductor manufacturing process because of its antifouling function.

The embodiments of the present disclosure discussed above have advantages over existing surface-modified structure and the method of modifying a surface, and the advantages are summarized below. The surface-modified structure and the method of modifying a surface of the present disclosure can easily change the surface properties without other side effects such as the damage of the organic film or substrate. In addition, the method of modifying a surface of the present disclosure may be applied to various kinds of the surfaces such as the surfaces of glass, organic film, semiconductor wafers, organic photoresists, metal containing photoresist (for example, Tin oxide, hafnium oxide, or lanthanum oxide containing photoresist), silicon oxide base middle layer, organic bottom anti-reflection coating (BARC), organic trilayer underlayer, and furniture without additional cost and apparatus. Furthermore, during the semiconductor manufacturing process, the surface-modified structure made by the modifying method of the present disclosure has the antifouling function, which can prevent the defect generation and optimize the semiconductor manufacturing process.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A surface-modified structure comprising:
a surface having a carboxylate group;
a modifier represented by NH₂—SO₂—, wherein a hydrogen bond formed between the carboxylate group of the surface and the modifier; and
an R group covalently bonded to the modifier.

2. The surface-modified structure of claim 1, wherein the R group is selected from a group consisting of fluoroalkyl group, alkyl group, polymer group, silanol group, metal group and metal oxide group.

3. The surface-modified structure of claim 1, wherein the hydrogen bond is formed between NH₂ of the modifier and the carboxylate group.

4. The surface-modified structure of claim 1, wherein the hydrogen bond is formed between the modifier and O⁻ of the carboxylate group.

5. The surface-modified structure of claim 1, wherein the R group is covalently bonded to S of the modifier.

6. The surface-modified structure of claim 1, wherein the R group is fluoroalkyl group represented by CₓF₂ₓ₊₁, and x is an integer from 1 to 6.

7. The surface-modified structure of claim 1, wherein the R group is C₄F₉.

8. The surface-modified structure of claim 1, wherein the R group is alkyl group comprising C1-C12 alkyl group.

9. The surface-modified structure of claim 1, wherein the R group is polymer group comprising —(CH₂CCH₃COOCH₃)ₙ—, —(CH₂CCH₃COOH)ₙ—, —(CH₂CCH₃COOR1)ₙ-, —(CH₂CHCOOR1)ₙ-, —(CH₂CHC₆H₅)ₙ— and —(CH₂CHOH)ₙ—, wherein R1 comprises methyl group, ethyl group, propyl group, benzyl group, phenol group, admantyl group, —C₆H₄COOH, lactone group, or acid labile group (ALG), and n is an integer from 1 to 20.

10. The surface-modified structure of claim 1, wherein the R group is metal group comprising titanium (Ti) or tungsten (W).

11. The surface-modified structure of claim 1, wherein the R group is metal oxide group comprising TiO_{y}, LaO_{y}, HfO_{y} or SnO_{y}, and y is in a range of 1.5 to 3.

12. A method of modifying a surface, the method comprising:
providing a substrate having the surface with a carboxylate group;
forming a compound represented by NH₂—SO₂—R, wherein R is selected from a group consisting of fluoroalkyl group, alkyl group, polymer group, silanol group, metal group and metal oxide group; and
forming a hydrogen bond between the compound and the carboxylate group of the surface.

13. The method of claim 12, wherein forming the compound represented by NH₂—SO₂—R, comprises:
providing a modifier represented by NH₂—SO₂—; and
covalently bonding the modifier and R.

14. The method of claim 12, wherein forming the hydrogen bond between the compound and the carboxylate group of the surface, comprises:
preparing a first solution comprising the compound; and
applying the first solution to the surface of the substrate.

15. The method of claim 14, wherein applying the first solution to the surface of the substrate, comprises:
rinsing the surface of the substrate with the first solution, or coating the first solution to the surface of the substrate.

16. The method of claim 14, wherein the first solution comprises:
the compound in a range of 0.005 to 5 part by weight; and
deionized water in a range of 95 to 99 parts by weight.

17. The method of claim 16, wherein the first solution further comprises a surfactant in a range of 0.05 to 0.8 part by weight.

18. The method of claim 12, wherein forming the hydrogen bond between the compound and the carboxylate group of the surface is under an alkaline condition.

19. The method of claim 12, wherein R is the fluoroalkyl group represented by CₓF₂ₓ₊₁, and x is an integer from 1 to 6.

20. The method of claim 12, wherein R is C4F9.
